(19) United States
(12) Patent Application Publication
(10) Pub. No.: US 2008/0311430 A1
(43) Pub. Date: Dec. 18, 2008

(54) Recording Medium

(76) Inventors: Jingsheng Chen, Singapore (SG); Chengjun Sun, Singapore (SG)

Correspondence Address: JACOBSON HOLMAN PLLC, 400 SEVENTH STREET N.W., SUITE 600, WASHINGTON, DC, 20004, US

(21) Appl. No.: 11/661,430

(22) PCT Filed: Aug. 30, 2005
(86) PCT No.: PCT/SG05/00295

§ 371 Date: Dec. 11, 2007

(30) Foreign Application Priority Data
Aug. 30, 2004 (SG) 200404701-5

(51) Int. Cl. G11B 5/66; C30B 19/00

(52) U.S. Cl. 428/827; 117/54

(57) ABSTRACT

A recording medium for perpendicular magnetic recording, the medium comprising: a magnetically soft underlayer (SUL) having a first crystalline orientation; and a second magnetic film; wherein the second magnetic film is induced to epitaxially grow from the SUL in a second crystalline orientation by controlling the first crystalline orientation.

### TECHNICAL FIELD

The invention concerns a recording medium for perpendicular magnetic recording.

### BACKGROUND OF THE INVENTION

Most double layered perpendicular recording systems include a recording head, a hard recording layer and a soft magnetic underlayer (“SUL”). The recording head has a single magnetic pole which generates a magnetic field with a strong perpendicular component to the film plane of the hard recording layer. Magnetic flux from the single magnetic pole passes through the hard recording layer and flows through the SUL. This converges the magnetic flux generated by the recording head, and increases the writing efficiency of the recording head.

Increasing the signal-to-noise ratio (SNR) increases magnetic recording and writing efficiency. One way to increase SNR is to reduce the separation between the recording head and the SUL to increase the magnetic field gradient. This will improve the concentration of the magnetic flux. Also, providing the hard recording layer with good perpendicular magnetic anisotropy is desirable.

To date, the prior art has been focussed on reducing the thickness of the intermediate layers between the hard recording layer and the SUL in order to improve the SNR.

### SUMMARY OF THE INVENTION

In a first preferred aspect, there is provided a recording medium for perpendicular magnetic recording, the medium comprising:
a magnetically soft underlayer (SUL) having a first crystalline orientation; and
a second magnetic film;
wherein the second magnetic film is induced to epitaxially grow from the SUL in a second crystalline orientation by controlling the first crystalline orientation.

In a second aspect, there is provided a method for producing a recording medium for perpendicular magnetic recording, the method comprising:
epitaxially growing a second magnetic film from a magnetically soft underlayer (SUL), the SUL having a first crystalline orientation; and
controlling the first crystalline orientation to induce the second magnetic film to epitaxially grow in a second crystalline orientation.

The recording medium may further comprise an underlayer having a third crystalline orientation to control the first crystalline orientation. The SUL may epitaxially grow to follow the third crystalline orientation.

The recording medium may further comprise a substrate.

The recording medium may further comprise a magnetic exchange de-coupling layer between the SUL and the second magnetic film.

The recording medium may further comprise a buffer layer between the SUL and the underlayer.

The second magnetic film may be deposited onto the surface of the SUL by sputtering.

The SUL, second magnetic film and the underlayer may be metallic thin films.

The SUL may have a body-centered-cubic (BCC) structure.

The second magnetic film may be a magnetically hard recording layer. The magnetically hard recording layer may have a face-centered tetragonal (FCT) structure.

The underlayer may have a body-centered-cubic (BCC) structure or face centered cubic (FCC) structure.

The first crystalline orientation may be a 002 crystalline orientation.

The second crystalline orientation may be a 001 crystalline orientation.

The third crystalline orientation may be a 002 crystalline orientation.

Preferably, the magnetically hard recording layer is made from FePt. Alternatively, the magnetically hard recording layer may be made from, CoPt or CoPtX. Element X may be MgO, SiO2, C, Ag, Cu, AlO, BN, B2O3, B or Cr.

Preferably, the SUL is made from FeCo. Alternatively, the SUL may be made from FeSi or FeCoX.

Element X may be one or two of C, O, SiO, AlO, B or Cu.

The underlayer may be made from one or two of MgO, NiAl, or CrX. Element X may be one or two of Ru, C, W, Ti, or Mo. Preferably, the substrate is made from ceramic or amorphous glass.

The magnetic exchange de-coupling layer may be made from MgO, CrX, Pt, NiAl, SrTi03, Au or Ag whose lattice match.

The buffer layer may be made from Pt, Ti, Mo or C. The buffer layer may be 0 to 4 nm.

Advantageously, the present invention reduces separation between the SUL and the recording head.

The present invention does not require an underlayer, intermediate layer or seed layer between the magnetically hard recording layer and the SUL in order to obtain 001 crystalline orientation of the hard recording layer.

### BRIEF DESCRIPTION OF THE DRAWINGS

An example of the invention will now be described with reference to the accompanying drawings, in which:

FIG. 1 is a structure diagram of an FePt/FeCo/CrRu recording medium;

FIG. 2 is a schematic graph of the lattice structures of FePt/FeCo/CrRu thin films;

FIG. 3 is a graph of x-ray θ-2θ scans of FeCo with varying CrRu thickness;

FIG. 4 is a graph of the (002) peak spreads of FeCo/CrRu thin films and FWHM;

FIG. 5 is a graph of the hysteresis loop of FeCo/Ru/FeCo/CrRu/glass recording medium;

FIG. 6 is a pictorial representation of recording medium in disc form; and

FIG. 7 is a graph of the XRD pattern and peak rocking curve of the recording medium.

### DETAILED DESCRIPTION OF THE DRAWINGS

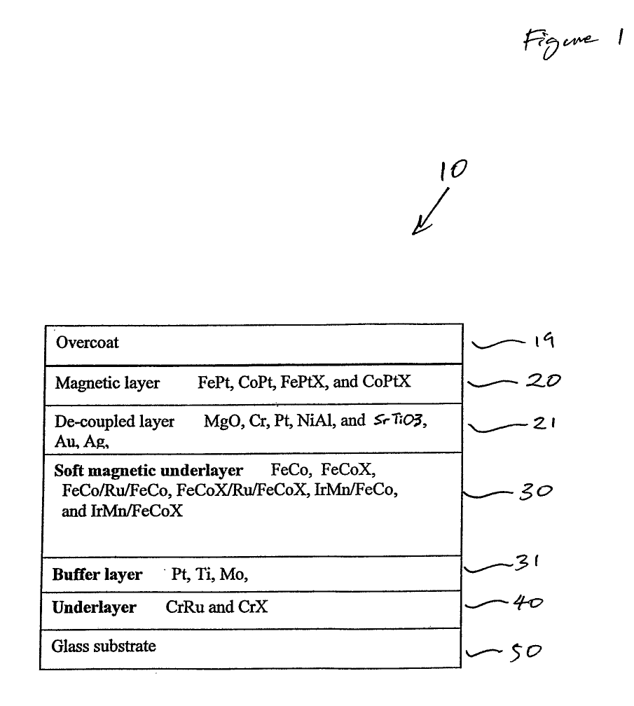

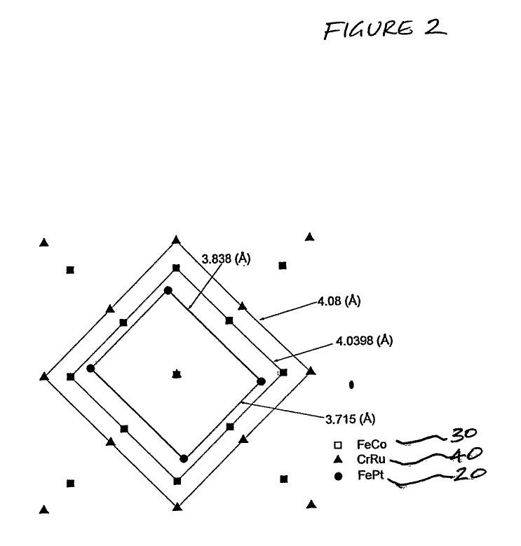

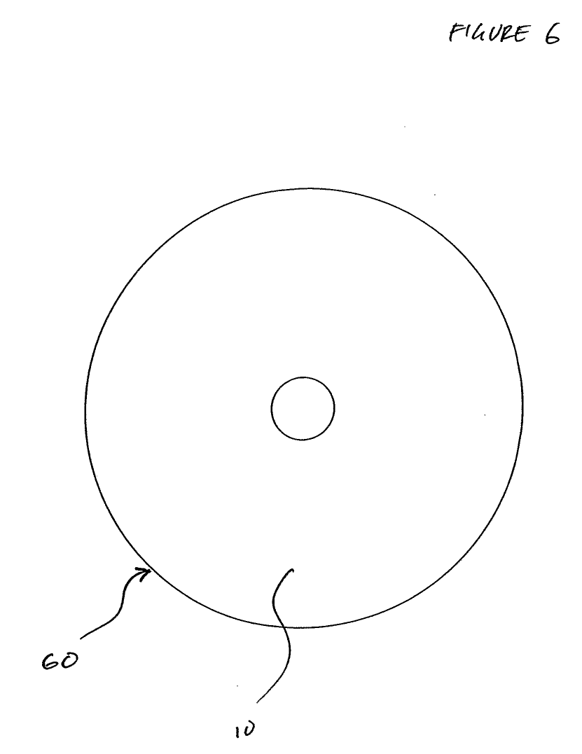

Referring to FIGS. 1 and 2, a double-layered recording medium 10 for high density perpendicular magnetic recording is provided. Turning to FIG. 6, the recording medium 10 is provided in a disk form, as a coating on a disk 60. Other forms are possible. Perpendicular recording is implemented by a single pole recording head (not shown) acting on the recording medium 10.

The recording medium 10 comprises a glass substrate 50 on top of which is a CrRu underlayer 40 having a (002) crystalline orientation. The CrRu underlayer 40 has a body-centered-cubic (BCC) structure. Other materials for the underlayer 40 include MgO, NiAl, CrX. Element X includes Ru, C, W, Ti or Mo. A magnetically soft underlayer (SUL) 30 is epitaxially grown from the CrRu underlayer 40. The SUL 30 is made from FeCo and has a BCC structure. Other materials for the SUL 30 include FeSi or FeCoX. Element X includes one or two of C, O, SiO, AlO, B or Cu. The SUL 30 introduces artificial anti-ferromagnetic coupling thereby to reduce the noise of the SUL 30. Also, pinning the domain of the SUL 30 reduces the noise of the SUL 30. For an SUL 30 made from FeSiX, doping X reduces the domain size. A magnetically hard recording layer 20 is epitaxially grown from the SUL 30. The SUL 30 is made from FeCo and has a BCC structure. The SUL 30 is in L10 phase and this reduces grain size thereby to increase the signal to noise ratio (SNR). SNR is proportional to the number of grains per grid. To overcome the superparamagnetism effect caused by a small grid, a high anisotropy material (high Ku) must be used for the recording medium 10. This is one reason for using FeCo, as this material has a high magnetic flux (Bs). Epitaxial growth occurs in such a way that the crystallographic structure of the SUL 30 is reproduced in the growing material, that is, FePt 20. The recording layer 20 has a 001 crystalline orientation. The recording layer 20 is made from FePt having a face-centered tetragonal (FCT) structure. Other suitable materials for the recording layer 20 include, CoPt or CoPtX. Element X includes MgO, SiO2, C, Ag, Cu, AlO, BN, B2O3, B or Cr. A thin protective overcoat 19 such as a diamond-like carbon may be applied over the recording layer 20. The film layers 20, 30, 40 are deposited to form the recording medium 10 by sputtering, in particular, magnetron sputtering. Examples of the recording medium 10 include fct-FePt (001)[100]//bcc-FeCo(002)[110]//bcc-CrRu(002)[110].

A magnetic exchange de-coupling layer 21 is provided between the recording layer 20 and SUL 30. The magnetic exchange de-coupling layer 21 is made from any one of MgO, Cr, Pt, NiAl, or SrTi03. The magnetic exchange de-coupling layer can also be made from Au or Ag whose lattice matches. The magnetic exchange de-coupling layer 21 may be a BCC or FCC structure so long as there is a lattice match with the SUL 30 and recording layer 20. A buffer layer 31 is also provided between the SUL 30 and the CrRu layer 40. The buffer layer 31 is made from any one of Pt, Ti, Mo or C. The buffer layer 31 is very thin, preferably between 0 to 4 nm in order to reduce the initial layer.

FePt films have extremely high magnetocrystalline anisotropy. Fabricating perpendicular media comprising a FePt (001) magnetic layer 20 and a FeCo SUL 30 is thus desirable. FeCo is able to induce FePt (001) magnetic films 20 for high-density perpendicular magnetic recording. In order to control or induce the FePt (001) easy axis orientation, the epitaxial growth of FePt/[FeCo/Ru/FeCo]/CrRu is manufactured according to the structure shown in FIG. 1. The layers from top to bottom of the medium 10 are arranged as a layer of FePt (001) 20, a layer of FeCo (002) 30, a layer of CrRu (002) 40 and the glass substrate 50. The underlayer 40 has a lattice match with the magnetic layer 20. The SUL 30 has a lattice match with the underlayer 40 and the magnetic layer 20.

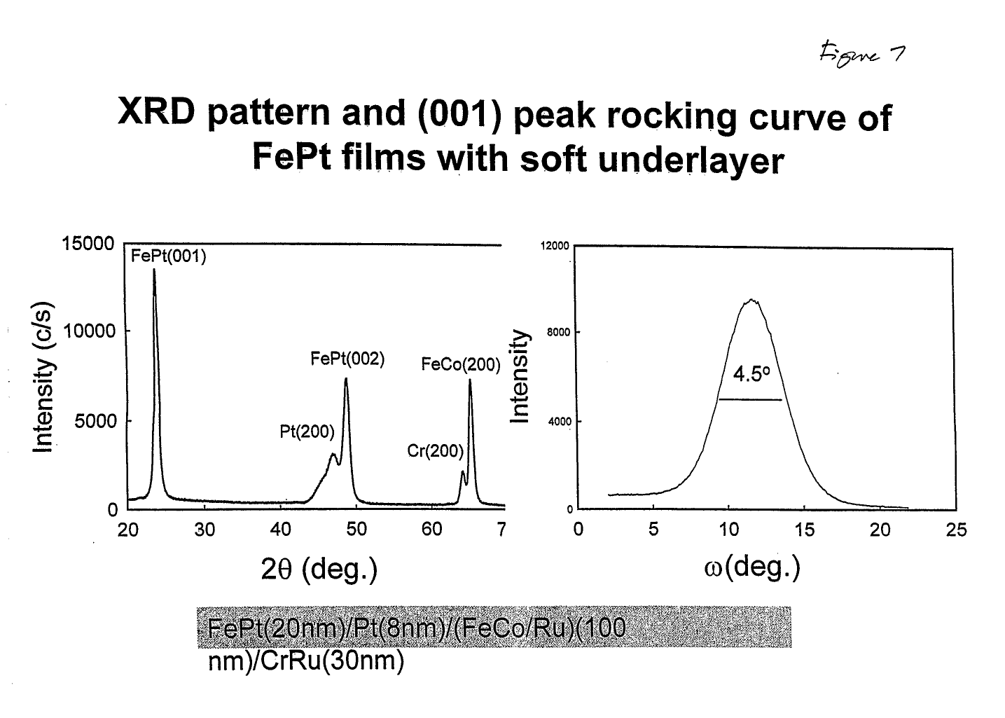

Referring to FIG. 7, the FeCo magnetically soft underlayer 30 is epitaxially grown on a CrRu (002) underlayer 40 to fabricate epitaxial growth of the FeCo/CrRu magnetically soft underlayer 30 with high saturation magnetization (Bₛ˜2.4 T). The FeCo magnetically soft film 30 is then used to induce the FePt (001) magnetically hard film 20 for high-density perpendicular magnetic recording. The misfit of the lattice constant between FePt (001) [100] and Cr (002) [110] is 5.8%. Strain from the misfit helps expand the a-axis and shrink the c-axis. Thus, L10 ordered FePt (001) texture is obtained at a relatively low temperature. The FePt ordering temperature and the FePt (001) orientation are able to be controlled or induced. Doping of FeCoX reduces the domain size and thereby reduces noise from the SUL 30.

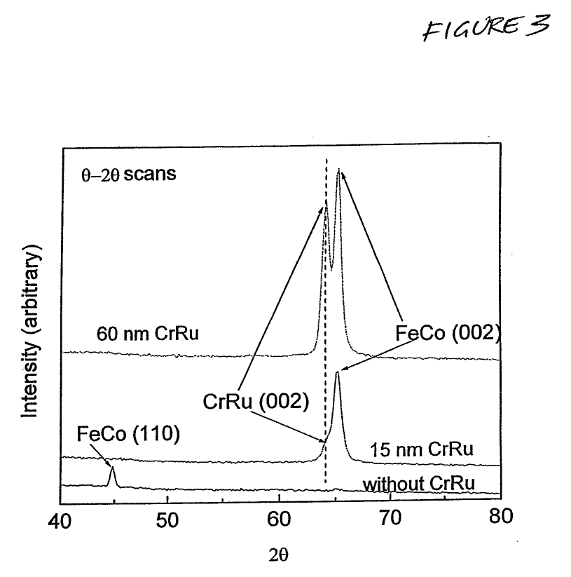

FIG. 3 shows the θ-2θ scans as a function of CrRu 40 thickness. The crystallinity of FeCo (002) 30 and CrRu (002) 40, as indicated by absolute intensity, increases with increasing CrRu 40 thickness.

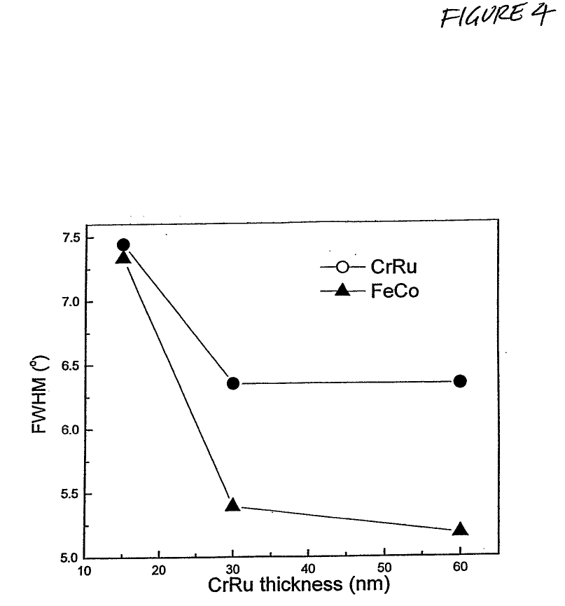

FIG. 4 shows the (002) peak spreads of the FeCo SUL 30 and CrRu underlayer 40, and the full width half maximum (FWHM) of the rocking curve obtained. The orientation of FeCo (002) 30 follows CrRu (002) 40, which narrows with increasing CrRu 40 thickness.

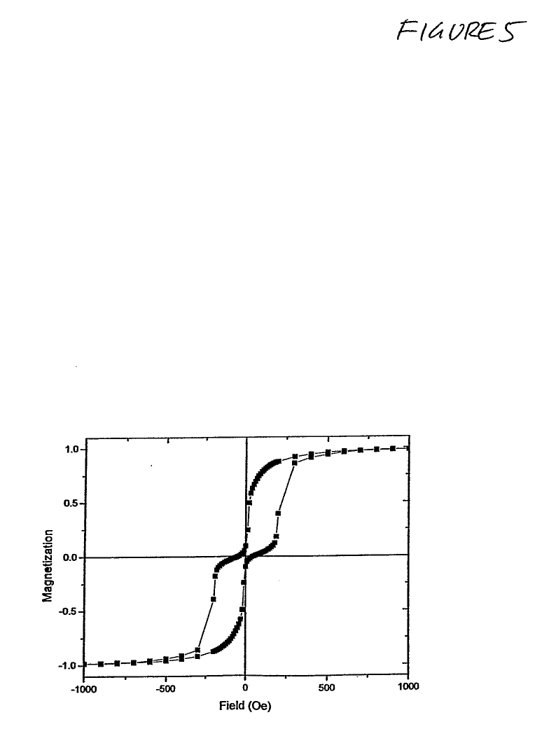

FIG. 5 shows the hysteresis loop of the FeCo/Ru/FeCo/CrRu/glass medium 10. Antiferro-coupled FeCo/Ru/FeCo thin films provides high saturation magnetization (Bₛ˜2.4 T) and low noise. This is ideal for perpendicular recording.

The recording medium 10 does not require additional layers between the SUL 30 and the recording layer 20. The CrRu underlayer 40 beneath the SUL 30 controls or induces the orientation of the SUL 30. The SUL 30 beneath the FePt magnetic layer 20 induces the orientation of the recording layer 20, in addition to converging the magnetic flux. Therefore, the crystalline orientation of the FePt layer 20 is controlled or induced while minimizing the separation between the SUL 30 and the recording head. The shorter spacing between the recording layer 20 and the SUL 30 maximises the head field.

It will be appreciated by persons skilled in the art that numerous variations and/or modifications may be made to the invention as shown in the specific embodiments without departing from the scope or spirit of the invention as broadly described. The present embodiments are, therefore, to be considered in all respects illustrative and not restrictive.

We claim:

1. A recording medium for perpendicular magnetic recording, the medium comprising:
a magnetically soft underlayer (SUL) having a first crystalline orientation; and
a second magnetic film;
wherein the second magnetic film is induced to epitaxially grow from the SUL in a second crystalline orientation by controlling the first crystalline orientation.

2. The medium according to claim 1, further comprising an underlayer having a third crystalline orientation to control the first crystalline orientation.

3. The medium according to claim 2, wherein the SUL epitaxially grows to follow the third crystalline orientation.

4. The medium according to claim 1, further comprising a substrate.

5. The medium according to claim 1, further comprising a magnetic exchange de-coupling layer between the SUL and the second magnetic film.

6. The medium according to claim 2, further comprising a buffer layer between the SUL and the underlayer.

7. The medium according to claim 2, wherein the SUL, second magnetic film and the underlayer are metallic thin films.

8. The medium according to claim 1, wherein the second magnetic film is a magnetically hard recording layer.

9. The medium according to claim 8, wherein the SUL has a body-centered-cubic (BCC) structure and has a lattice match with the magnetically hard recording layer and the underlayer.

10. The medium according to claim 2, wherein the underlayer has a body-centered-cubic (BCC) structure and has a lattice match with the magnetically hard recording layer.

11. The medium according to claim 1, wherein the second crystalline orientation is a 001 crystalline orientation.

12. The medium according to claim 1, wherein the first crystalline orientation is a 002 crystalline orientation.

13. The medium according to claim 2, wherein the third crystalline orientation is a 002 crystalline orientation.

14. The medium according to claim 8, wherein the magnetically hard recording layer is made from FePt, FePtX, CoPt or CoPtX.

15. The medium according to claim 14, wherein element X is MgO, SiO2, C, Ag, Cu, AlO, BN, B2O3, B or Cr.

16. The medium according to claim 1, wherein the SUL is made from FeCo, FeSi, FeCoX, FeCo/Ru/FeCo, FeCoX/Ru/FeCoX, IrMn/FeCo or IrMn/FeCoX.

17. The medium according to claim 16, wherein IrMn is an antiferromagnetic material.

18. The medium according to claim 16, wherein element X is one or two of C, O, SiO, AlO, B or Cu.

19. The medium according to claim 10, wherein the underlayer is made from one or two of MgO, NiAl, or CrX.

20. The medium according to claim 19, wherein element X is Ru, C, W, Ti or Mo.

21. The medium according to claim 4, wherein the substrate is made from glass.

22. The medium according to claim 5, wherein the magnetic exchange de-coupling layer is made from MgO, Cr, Pt, NiAl, or SrTi03.

23. The medium according to claim 6, wherein the buffer layer is made from Pt, Ti, Mo or C.

24. The medium according to claim 6, wherein the buffer layer is between 0 to 4 nm in thickness.

25. A method for producing a recording medium for perpendicular magnetic recording, the method comprising:
epitaxially growing a second magnetic film from a magnetically soft underlayer (SUL), the SUL having a first crystalline orientation; and
controlling the first crystalline orientation to induce the second magnetic film to epitaxially grow in a second crystalline orientation.

26. The method according to claim 25, further comprising an underlayer having a third crystalline orientation to control the first crystalline orientation.

27. The method according to claim 26, wherein the SUL epitaxially grows to follow the third crystalline orientation.

28. The method according to claim 27, further comprising a substrate.

29. The method according to claim 27, further comprising a magnetic exchange de-coupling layer between the SUL and the second magnetic film.

30. The method according to claim 27, further comprising a buffer layer between the first film and the underlayer.

31. The method according to claim 28, wherein the SUL, second magnetic film and the underlayer are metallic thin films.

32. The method according to claim 28, wherein the second magnetic film is a magnetically hard recording layer.

33. The method according to claim 32, wherein the SUL has a body-centered-cubic (BCC) structure.

34. The method according to claim 28, wherein the underlayer has a body-centered-cubic (BCC) structure.

35. The method according to claim 27, wherein the second crystalline orientation is a 001 crystalline orientation.

36. The method according to claim 27, wherein the first crystalline orientation is a 002 crystalline orientation.

37. The method according to claim 28, wherein the third crystalline orientation is a 002 crystalline orientation.

38. The method according to claim 32, wherein the magnetically hard recording layer is made from FePt, FePtX, CoPt or CoPtX.

39. The method according to claim 38, wherein element X is MgO, SiO2, C, Ag, Cu, AlO, BN, B2O3, B or Cr.

40. The method according to claim 25, wherein the SUL is made from FeCo, FeSi, FeCoX, FeCo/Ru/FeCo, FeCoX/Ru/FeCoX, IrMn/FeCo or IrMn/FeCoX.

41. The method according to claim 40, wherein IrMn is an antiferromagnetic material.

42. The medium according to claim 40, wherein element X is one or two of C, O, SiO, AlO, B or Cu.

43. The method according to claim 34, wherein the underlayer is made from one or two of MgO, NiAl, or CrX.

44. The method according to claim 43, wherein element X is Ru, C, W, Ti or Mo.

45. The method according to claim 28, wherein the substrate is made from glass.

46. The method according to claim 29, wherein the magnetic exchange de-coupling layer is made from MgO, Cr, Pt, NiAl, or SrTi03.

47. The method according to claim 30, wherein the buffer layer is made from Pt, Ti, Mo or C.

48. The method according to claim 30, wherein the buffer layer is between 0 to 4 nm in thickness.

49. A disk having a computer-readable medium for carrying computer-executable instructions, the medium comprising a magnetically soft underlayer (SUL) having a first crystalline orientation; and a second magnetic film; wherein the second magnetic film is induced to epitaxially grow from the SUL in a second crystalline orientation by controlling the first crystalline orientation.
